(19) United States
(12) Patent Application Publication
(10) Pub. No.: US 2026/0198017 A1
(43) Pub. Date: Jul. 9, 2026

(54) SEMICONDUCTOR DEVICE AND METHOD OF MANUFACTURING SEMICONDUCTOR DEVICE

(71) Applicant: SK hynix Inc., Icheon-si Gyeonggi-do (KR)

(72) Inventors: Jae Young OH, Icheon-si Gyeonggi-do (KR); Jin Taek PARK, Icheon-si Gyeonggi-do (KR); Dong Hwan LEE, Icheon-si Gyeonggi-do (KR)

(73) Assignee: SK hynix Inc., Icheon-si Gyeonggi-do (KR)

(21) Appl. No.: 19/189,436

(22) Filed: Apr. 25, 2025

(30) Foreign Application Priority Data
Jan. 7, 2025 (KR) 10-2025-0002364

(51) Int. Cl. H10B 80/00; H01L 23/00; H01L 25/00; H01L 25/065; H01L 25/18

(52) U.S. Cl. CPC H10B 80/00; H10W 90/00; H10W 80/163; H10W 80/312; H10W 80/327; H10W 90/792

(57) ABSTRACT

A semiconductor device includes a first structure having a first central axis, a first interconnection structure located on the first structure and having a second central axis aligned with the first central axis, a first bonding structure located on the first interconnection structure and having a third central axis misaligned with the first central axis, a second bonding structure located on the first bonding structure and having a fourth central axis misaligned with the first central axis, a second interconnection structure located on the second bonding structure and having a fifth central axis misaligned with the first central axis, and a second structure located on the second interconnection structure and having a sixth central axis misaligned with the first central axis.

### CROSS-REFERENCE TO RELATED APPLICATION

The present application claims priority under 35 U.S.C. § 119(a) to Korean Patent Application No. 10-2025-0002364 filed in the Korean Intellectual Property Office on Jan. 7, 2025, which application is incorporated herein by reference in its entirety.

### BACKGROUND

### 1. Technical Field

The present disclosure relates to an electronic device and a method of manufacturing the electronic device, including but not limited to a semiconductor device and a method of manufacturing the semiconductor device.

### 2. Related Art

Integration density of a semiconductor device is determined by an area occupied by a unit memory cell. As improvements in integration density of a semiconductor device in which a memory cell is formed as a single layer on a substrate reaches a limit, three-dimensional semiconductor devices in which memory cells are stacked on a substrate are under development. Various structures and manufacturing methods are being developed to improve operation reliability of the semiconductor device.

### SUMMARY

According to an embodiment of the present disclosure, a semiconductor device may include a first structure having a first central axis, a first interconnection structure located on the first structure and having a second central axis aligned with the first central axis, a first bonding structure located on the first interconnection structure and having a third central axis misaligned with the first central axis, a second bonding structure located on the first bonding structure and having a fourth central axis misaligned with the first central axis, a second interconnection structure located on the second bonding structure and having a fifth central axis misaligned with the first central axis, and a second structure located on the second interconnection structure and having a sixth central axis misaligned with the first central axis.

According to an embodiment of the present disclosure, a method of manufacturing a semiconductor device may include forming a first structure using a first hard mask having a first central axis, aligning a second central axis of a second hard mask with the first central axis, forming a first interconnection structure connected to the first structure using the second hard mask, aligning a third central axis of a third hard mask with the first central axis, forming a first bonding structure connected to the first interconnection structure using the third hard mask, forming a second structure using a fourth hard mask having a fourth central axis misaligned with the first central axis, forming a second interconnection structure connected to the second structure using a fifth hard mask having a fifth central axis misaligned with the first central axis, aligning a sixth central axis of a sixth hard mask with the first central axis, forming a second bonding structure connected to the second interconnection structure using the sixth hard mask, and bonding the first bonding structure to the second bonding structure.

A semiconductor device comprising a first wafer including a first structure having a first central axis, a second structure having a second central axis misaligned with the first central axis; and a second wafer bonded to the first wafer and including third structure having a third central axis misaligned with the first central axis and a fourth structure having a fourth central axis misaligned with the first central axis.

### BRIEF DESCRIPTION OF THE DRAWINGS

FIG. 1 illustrates a semiconductor device according to an embodiment of the present disclosure.

FIG. 2A through FIG. 2F illustrate a semiconductor device according to an embodiment of the present disclosure.

FIG. 3 is a flowchart illustrating a method of manufacturing a semiconductor device according to an embodiment of the present disclosure.

FIG. 4A, FIG. 4B, FIG. 4C, FIG. 5A through FIG. 5F, FIG. 6A, and FIG. 6B illustrate a semiconductor device formed utilizing a method of manufacturing a semiconductor device according to an embodiment of the present disclosure.

### DETAILED DESCRIPTION

The present disclosure describes a semiconductor device and a method of manufacturing the semiconductor device having a stable structure and an improved characteristic.

According to the present technology, a semiconductor device having a stable structure and improved reliability is described.

Embodiments of the present disclosure are described in detail with reference to the accompanying drawings. Specific structural or functional descriptions of embodiments are provided as examples to describe concepts that are disclosed in the present application. Examples or embodiments in accordance with the concepts may be carried out in various forms, and the scope of the present disclosure is not limited to the examples or embodiments described in this specification.

Terms such as “under,” “on,” “uppermost,” and other terms implying relative spatial relationship or orientation are utilized only for the purpose of ease of description or reference to a drawing and are not otherwise limiting.

The cross-hatching throughout the figures illustrates corresponding or similar areas between the figures rather than indicating the materials associated with the areas.

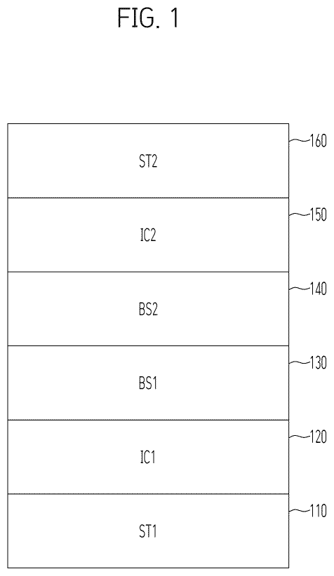

FIG. 1 illustrates a semiconductor device according to an embodiment of the present disclosure.

Referring to FIG. 1, the semiconductor device includes a first structure ST1, a second structure ST1, a first interconnection structure IC1, a second interconnection structure IC2, a first bonding structure BS1, and a second bonding structure BS2. For example, the semiconductor device has a form in which the first structure ST1, the first interconnection structure IC1, the first bonding structure BS1, the second bonding structure BS2, the second interconnection structure IC2, and the second structure ST2 are stacked. In the example of FIG. 1, a stack direction includes a third direction III, for example, orthogonal to a first direction I and a second direction II.

The first structure ST1 includes a peripheral circuit. For example, the first structure ST1 includes a transistor and the like. The first structure ST1 has a first central axis. A central axis includes an axis passing through a central point of at least one component included in a structure. For example, a first central axis includes an axis extending in a direction parallel to the third direction III and passing through a central point of at least one component included in the peripheral circuit of the first structure.

The first interconnection structure IC1 is located on the first structure ST1 and connected to the first structure ST1. The first interconnection structure IC1 includes first connection vias and first connection lines. At least one of the first connection vias is connected to the first structure ST1. The first connection lines interconnect the first connection vias.

The first connection lines include uppermost first connection lines, also referred to as a first set of first connection lines, and additional first connection lines, also referred to as a second set of first connection lines. The uppermost first connection lines include first connection lines located most distant from the first structure ST1 among the first connection lines. Alternatively phrased, the uppermost first connection lines include first connection lines located nearest to the second structure ST2 among the first connection lines. The uppermost first connection lines have a width greater than a width of the additional first connection lines.

The first interconnection structure IC1 has a second central axis. The second central axis is aligned with the first central axis. For example, the first connection via has the second central axis and is aligned with the first central axis of a component of a peripheral circuit connected to a connection via. Thus, the first connection via is aligned with the component of the peripheral circuit connected to the first connection via.

The first bonding structure BS1 is located on the first interconnection structure IC1 and is connected to the first interconnection structure IC1. The first bonding structure BS1 includes first bonding vias and first bonding pads. The first bonding vias are correspondingly connected to the first connection lines. For example, the first bonding vias are correspondingly connected to the uppermost first connection lines. The first bonding pads are correspondingly connected to the first bonding vias.

The first bonding structure BS1 has a third central axis. The third central axis is misaligned with the first central axis. For example, the first bonding via is connected to the uppermost first connection line at a location other than a location corresponding to a central point of the uppermost first connection line because the uppermost first connection line has a width greater than a width of the additional first connection lines. Misalignment of central axes includes misalignment between the central axes.

The second bonding structure BS2 is located on the first bonding structure BS1, and is connected to the first bonding structure BS1. The second bonding structure BS2 includes second bonding vias and second bonding pads. The second bonding pads are correspondingly connected to the first bonding pads. The second bonding vias are correspondingly connected to the second bonding pads. The second bonding structure BS2 has a fourth central axis. The fourth central axis is misaligned with the first central axis and is aligned with the third central axis.

The second interconnection structure IC2 is located on the second bonding structure BS2 and is connected to the second bonding structure BS2. The second interconnection structure IC2 s connected to the second structure ST2. The second interconnection structure IC2 includes second connection vias and second connection lines. The second connection lines are correspondingly connected to the second bonding vias, and the second connection vias are correspondingly connected to the second connection lines. The second interconnection structure IC2 has a fifth central axis. The fifth central axis is misaligned with the first central axis and is aligned with the fourth central axis.

The second structure ST2 is located on the second interconnection IC2. The second structure ST2 includes a stacked memory cell. The second structure ST2 includes a gate structure and through structures extending through the gate structure. The gate structure includes stacked conductive lines. The conductive lines include a word line, a bit line, a selection line, and the like. The through structures includes channel structures, electrode structures, and the like. The memory cells are located in areas where the through structures and the conductive lines intersect.

The second structure ST2 has a sixth central axis. The sixth central axis is misaligned with the first central axis and is aligned with the fifth central axis. The third central axis, the fourth central axis, the fifth central axis, and the sixth central axis are aligned with each other, and the third central axis, the fourth central axis, the fifth central axis, and the sixth central axis are misaligned with the first central axis and the second central axis.

In the example of FIG. 1, the first structure ST1 includes the peripheral circuit and the second structure ST2 includes the memory cell array, although the first structure ST1 and the second structures ST2 are not limited to these examples. In one example, the first structure ST1 includes the memory cell array and the second structure ST2 includes the peripheral circuit. Alternatively, both the first structure ST1 and the second structure ST2 may include memory cell arrays.

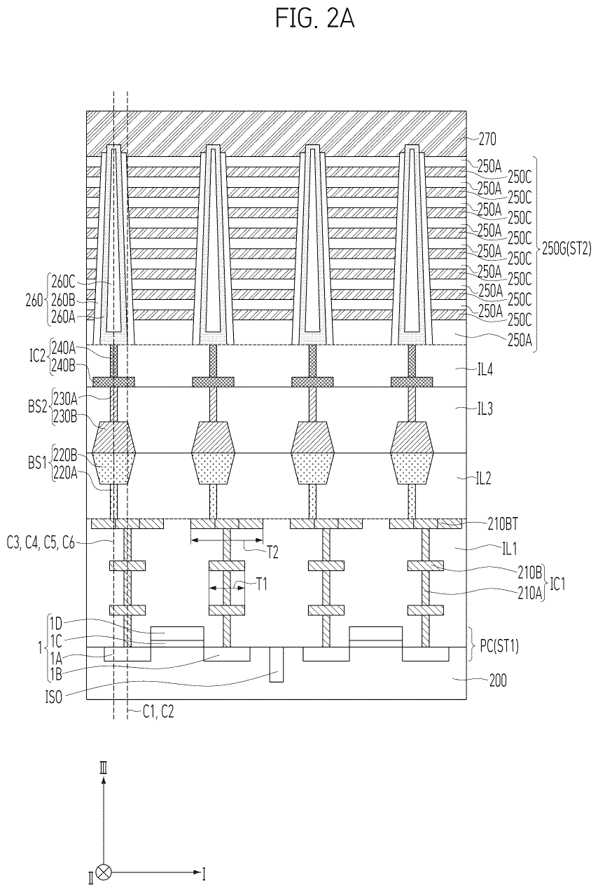

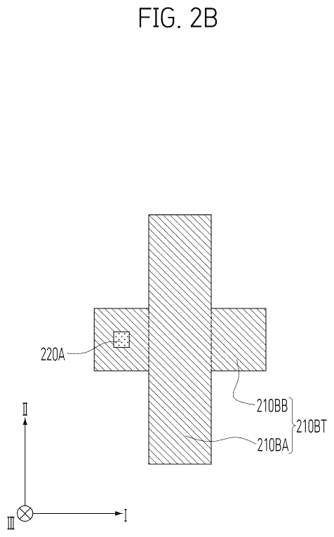

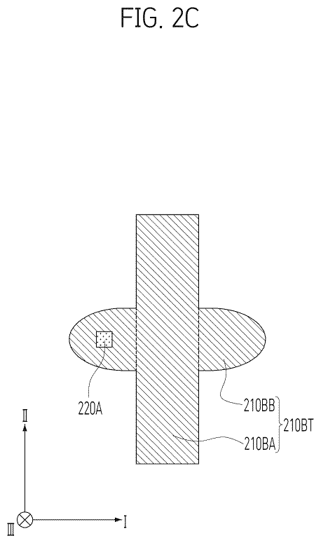

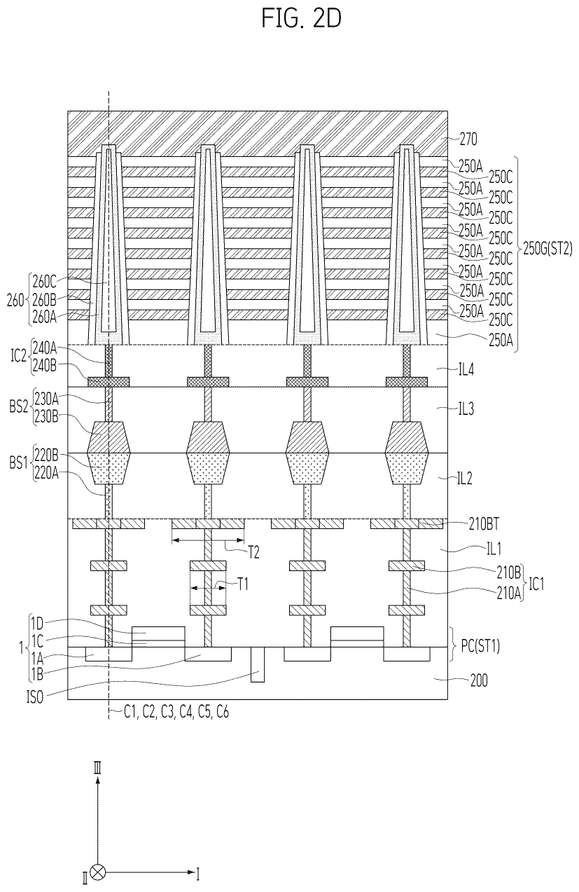

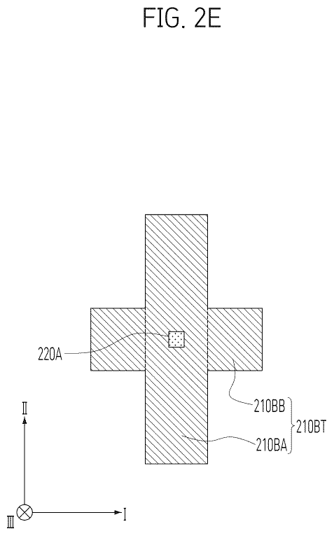

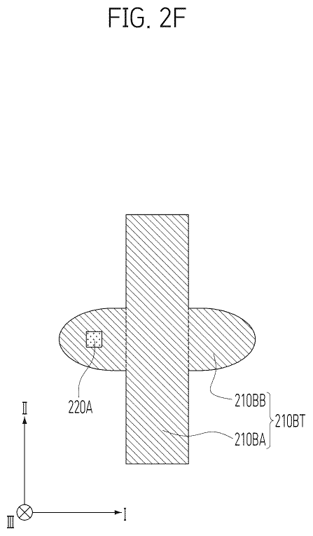

FIG. 2A through FIG. 2F illustrate a semiconductor device according to an embodiment of the present disclosure.

Referring to FIG. 2A and FIG. 2D, the semiconductor device includes a first structure ST1, a second structure ST2, a first interconnection structure IC1, a second interconnection structure IC2, a first bonding structure BS1, and a second bonding structure BS2. The semiconductor device includes a substrate 200, a source structure 270, a first interlayer insulating layer IL1, a second interlayer insulating layer IL2, a third interlayer insulating layer IL3, and a fourth interlayer insulating layer IL4.

The first structure ST1 is located on and within the substrate 200. The first structure ST1 includes a peripheral circuit PC, and the peripheral circuit PC includes a transistor 1 and the like. The transistor 1 includes junctions 1A and 1B, a gate electrode 1D, and a gate insulating layer 1C. In this example, the gate insulating layer 1C is located between the gate electrode 1D and the substrate 200. The first structure ST1 has a first central axis C1. For example, the transistor 1 has the first central axis C1, and the first junction 1A has the first central axis C1. An element isolation layer ISO is located within the substrate 200, an active area is delineated by the element isolation layer ISO, and the transistor 1 is located within the active area.

The first interconnection structure IC1 is located on the first structure ST1 and is connected to the first structure ST1. The first interconnection structure IC1 includes first connection vias 210A and first connection lines 210B, 210BT. In this example, the first interconnection structure IC1 is located within a first interlayer insulating layer IL1. The first interlayer insulating layer IL1 is located on the substrate 200. At least one of the first connection vias 210A is connected to the peripheral circuit PC. The first connection lines 210B interconnect the first connection vias 210A.

The first connection lines includes uppermost first connection lines 210BT and additional first connection lines 210B. Each of the uppermost first connection lines 210BT include a body 210BA extending in a second direction II and protrusions 210BB protruding from the body 210BA in a first direction I, for example, orthogonal to the second direction II. The protrusions 210BB may have a quadrangular shape as shown in FIG. 2B or an elliptical shape as shown in FIG. 2C. The present disclosure is not limited to these examples, and the protrusions 210BB may have a circular shape and so forth. The additional first connection lines 210B have a first width T1, and the uppermost first connection lines 210BT have a second width T2 greater than the first width T1.

The first interconnection structure IC1 has a second central axis C2. For example, the first connection vias 210A and the first connection lines 210B have the second central axis C2. The second central axis C2 is aligned with the first central axis C1. For example, the uppermost first connection line 210BT, the first connection via 210A, and the additional first connection lines 210B have the second central axis C2 and are aligned with the first central axis C1 of the first junction 1A. The first interconnection structure IC1 may include a conductive material such as tungsten, and the first interlayer insulating layer IL1 may include an insulating material such as oxide.

The first bonding structure BS1 is located on the first interconnection structure IC1, and may be connected to the first interconnection structure IC1. The first bonding structure BS1 may be located in a second interlayer insulating layer IL2. In this example, the second interlayer insulating layer IL2 is located on the first interlayer insulating layer IL1. The second interlayer insulating layer IL2 may include an insulating material such as oxide, and the first bonding structure BS1 may include a conductive material such as tungsten or copper.

The first bonding structure BS1 includes first bonding vias 220A and first bonding pads 220B. The first bonding structure BS1 has a third central axis C3. The third central axis C3 is misaligned with the first central axis C1. For example, the first bonding via 220A and the first bonding pad 220B have the third central axis C3 and are misaligned with the second central axis C2 of the uppermost first connection line 210BT.

The first bonding pads 220B are correspondingly connected to the first bonding vias 220A. The first bonding vias 220A are correspondingly connected to the uppermost first connection lines 210BT. In this example, the first bonding vias 220A are correspondingly connected to the protrusions 210BB of the uppermost first connection lines 210BT. Because the third central axis C3 of the first bonding via 220A and the second central axis C2 of the uppermost first connection wiring 210BT are misaligned, the first bonding via 220A is connected to the protrusion 210BB of the uppermost first connection line 210BT. In this example, even though the third central axis C3 and the second central axis C2 are misaligned, the first bonding structure BS1 and the first interconnection structure IC1 are connected.

The second bonding structure BS2 is located on the first bonding structure BS1 and is connected to the first bonding structure BS1. The second bonding structure BS2 is located in a third interlayer insulating layer IL3. In this example, the third interlayer insulating layer IL3 is located on the second interlayer insulating layer IL2. The second bonding structure BS2 includes second bonding vias 230A and second bonding pads 230B. The second bonding structure BS2 has a fourth central axis C4. The fourth central axis C4 is misaligned with the first central axis C1 and is aligned with the third central axis C3. The third interlayer insulating layer IL3 may include an insulating material such as oxide, and the second bonding structure BS2 may include a conductive material such as tungsten or copper.

The second interconnection structure IC2 is located on the second bonding structure BS2 and is connected to the second bonding structure BS2. The second interconnection structure IC2 is located in a fourth interlayer insulating layer IL4. In this example, the fourth interlayer insulating layer IL4 is located on the third interlayer insulating layer IL3. The second interconnection structure IC2 includes second connection vias 240A and second connection lines 240B. The second interconnection structure IC2 has a fifth central axis C5. The fifth central axis C5 is misaligned with the first central axis C1 and is aligned with the fourth central axis C4. The fourth interlayer insulating layer IL4 may include an insulating material such as oxide, and the second interconnection structure IC2 may include a conductive material such as tungsten.

The second structure ST2 is located on the second interconnection structure IC2, and may be connected to the second interconnection structure IC2. The second structure ST2 includes a gate structure 250G and channel structures 260 extending through the gate structure 250G. The gate structure 250G includes insulating layers 250A alternately stacked with conductive layers 250B. The conductive layers 250B include conductive lines such as a word line, a bit line, a selection line, and the like.

The channel structures 260 extend into the source structure 270 through the gate structure 250G. In this example, the source structure 270 is located on the second structure ST2. For example, the source structure 270 is located on the gate structure 250G. Each of the channel structures 260 includes a channel layer 260A and a memory layer 260B surrounding the channel layer 260A. Each of the channel structures 260 includes an insulating core 260C within the channel layer 260A. In this example, the channel layer 260A is connected to the source structure 270.

The second structure ST2 has a sixth central axis C6. For example, the channel structure 260 has the sixth central axis C6. The sixth central axis C6 is misaligned with the first central axis C1 and is aligned with the fifth central axis C5. In this example, the channel structures 260 are correspondingly aligned with the second connection lines 240B. In this example, the second connection lines 240B are conductive lines used as bit lines.

In FIG. 2D, each of the first central axis C1, the second central axis C2, the third central axis C3, the fourth central axis C4, the fifth central axis C5, and the sixth central axis C6 are aligned. In this example, the uppermost first connection lines 210BT need not have a relatively greater width that the additional first connection lines 210B.

In FIG. 2A, the first central axis C1 and the second central axis C2 are aligned with each other, and the third central axis C3, the fourth central axis C4, the fifth central axis C5, and the sixth central axis C6 are aligned with each other. In this example, the first central axis C1 and the second central axis C2, are misaligned with the third central axis C3, the fourth central axis C4, the fifth central axis C5, and the sixth central axis C6. The second central axis C2 of the first interconnection structure IC1 and the third central axis C3 of the first bonding structure BS1 are misaligned, and to obtain a sufficient landing margin between the first interconnection structure IC1 and the first bonding structure BS1, the uppermost first connection lines 210BT is formed with a greater width.

According to the structure described, because the uppermost first connection lines 210BT has a relatively greater width, a sufficient landing margin is obtained, and even though misalignment occurs between the first interconnection structure IC1 and the first bonding structure BS1, the first interconnection structure IC1 and the first bonding structure BS1 are connected.

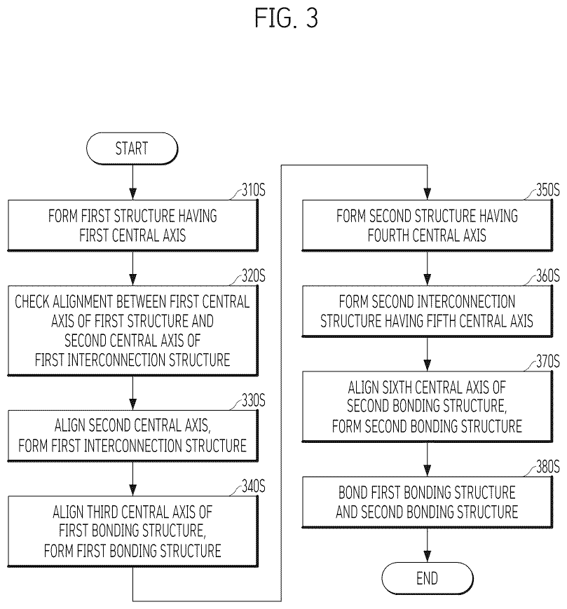

FIG. 3 is a flowchart illustrating a method of manufacturing a semiconductor device according to an embodiment of the present disclosure. The processes of the flowchart may be performed in a different order and may include fewer or additional processes than described and shown in FIG. 3.

Referring to FIG. 3, a first structure having a first central axis is formed 310S. For example, the first structure is formed using a first hard mask having the first central axis. In this example, the first structure has the first central axis. The first structure includes stacked memory cells. The first structure includes a gate structure and through structures extending through the gate structure. The gate structure includes stacked conductive lines. The conductive lines include a word line, a bit line, a selection line, and so forth. The through structures include channel structures, electrode structures, and so forth. The memory cells are located in areas where the through structures and conductive lines intersect.

A second hard mask that forms the first interconnection structure is formed. The first interconnection structure having a second central axis is formed utilizing the second hard mask. In this example, the second hard mask has the second central axis. The second central axis of the second hard mask may or may not be aligned with the first central axis of the first structure. For example, the alignment between the first central axis of the first structure and the second central axis of the first interconnection structure is checked 320S, and when the second central axis of the second hard mask is misaligned with the first central axis, the second hard mask is moved such that the second central axis and the first central axis are aligned. The first interconnection structure is formed 330S on the first structure and is connected to the first structure. The first interconnection structure includes first connection vias and first connection lines.

A third hard mask that form the first bonding structure is formed. The third central axis of the third hard mask may or may not be aligned with the first central axis. When the third central axis of the third hard mask is misaligned with the first central axis, the third hard mask is aligned by adjusting, moving, or calibrating the third hard mask such that the third central axis is aligned with the first central axis. A first bonding structure having a third central axis is formed 340S.

The first bonding structure is formed on the first interconnection structure and is connected to the first interconnection structure. The first bonding structure includes first bonding vias and first bonding pads. Accordingly, a first wafer including a first structure having the first central axis, the first interconnection structure having the second central axis, and the first bonding structure having the third central axis are formed with the first central axis, the second central axis, and the third central axis aligned.

A fourth hard mask that forms the second structure is formed. The second structure having a fourth central axis is formed 350S. The fourth hard mask need not be aligned with the first central axis because the second structure is connected even when misaligned with other structures by forming the second interconnection structure in a different process. For example, when the fourth hard mask is aligned with the first central axis need not be separately manufactured, manufacturing costs of the semiconductor device may be reduced. The second structure includes a peripheral circuit.

A fifth hard mask that forms the second interconnection structure is formed. The second interconnection structure having a fifth central axis is formed 360S. The fifth hard mask need not be aligned with the first central axis because the uppermost second connection lines are connected to the second bonding structure formed in a different process during which the uppermost second connection lines are formed with a relatively greater width during a process of forming the second interconnection structure. In this example, the fifth central axis is aligned with the fourth central axis. In this example, because the fifth hard mask need not be separately manufactured, manufacturing costs of the semiconductor device may be reduced. The second interconnection structure is formed on the second structure and is connected to the second structure. The second interconnection structure includes second connection vias and second connection lines. In this example, the second connection lines include the uppermost second connection lines, also referred to as a first set of second connection lines, and additional second connection lines, also referred to as a second set of first connection lines. The uppermost second connection lines are formed having a width greater than a width of the additional second connection lines.

A sixth hard mask that forms the second bonding structure is formed. The sixth central axis of the sixth hard mask may or may not be aligned with the first central axis of the first structure. For example, the sixth hard mask is moved, adjusted, or calibrated to be aligned with the first central axis. In an embodiment, the sixth hard mask may be moved the same distance as the distance the second mask was moved to align with the first central axis. The second bonding structure having a sixth central axis is formed 370S. The second bonding structure includes second bonding vias and second bonding pads. Accordingly, a second wafer including the second structure, the second interconnection structure, and the second bonding structure are formed.

The first bonding structure and the second bonding structure are bonded 380S. For example, the first bonding pads are bonded to corresponding second bonding pads. Accordingly, the first structure and the second structure are electrically connected through the first interconnection structure, the first bonding structure, the second bonding structure, and the second interconnection structure.

According to an embodiment of the present disclosure, after forming the first structure having the first central axis, the second hard mask and the third hard mask that form the first interconnection structure and the first bonding structure are aligned, and the sixth hard mask that forms the second bonding structure may be aligned. Thus, the second hard mask, the third hard mask, and the sixth hard mask are separately manufactured.

The fourth hard mask and the fifth hard mask that form the second interconnection structure and the second structure formed under the second bonding structure need not be separately manufactured. By aligning, adjusting, or calibrating only the sixth hard mask that forms the second bonding structure bonded of the second wafer to the first bonding structure of the first wafer, the fourth hard mask and the fifth hard mask that form the second structure and the second interconnection structure of the second wafer need not be aligned, adjusted, calibrated, or moved. In this example, because the fourth hard mask and the fifth hard mask need not be separately manufactured, manufacturing costs of the semiconductor device may be reduced.

In this example, the first structure is a memory cell array and the second structure includes the peripheral circuit, although the first structure and the second structure are not limited to these examples. In one example, the first structure includes the peripheral circuit and the second structure is the memory cell array. Alternatively, both the first structure and the second structure may include memory cell arrays.

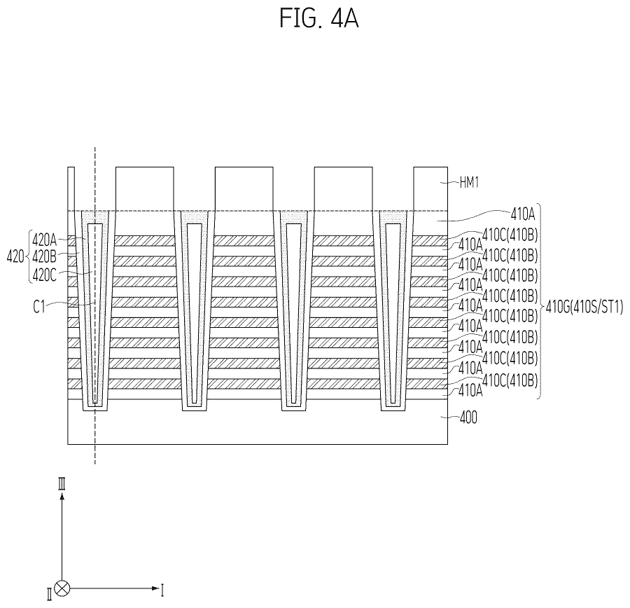

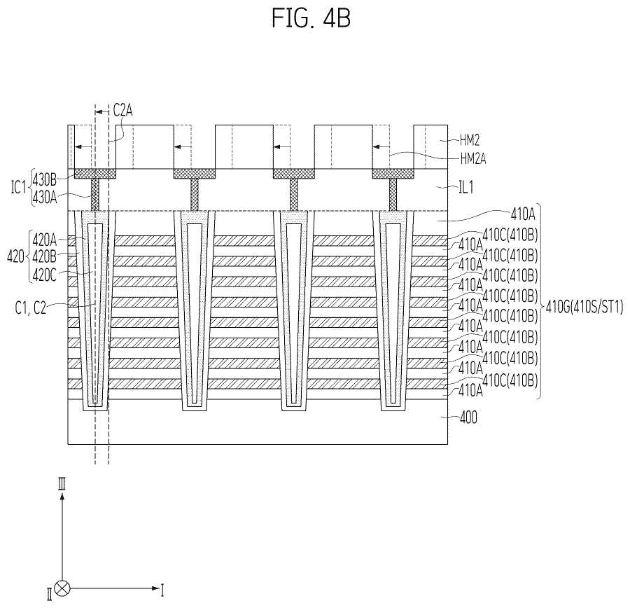

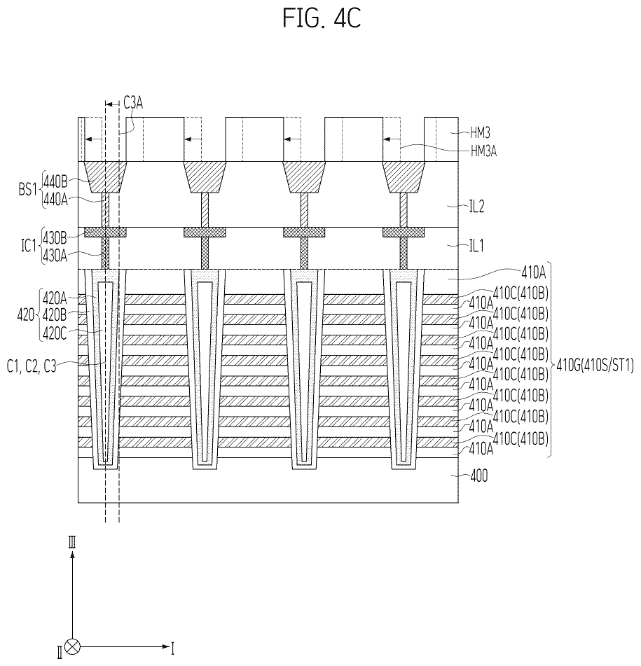

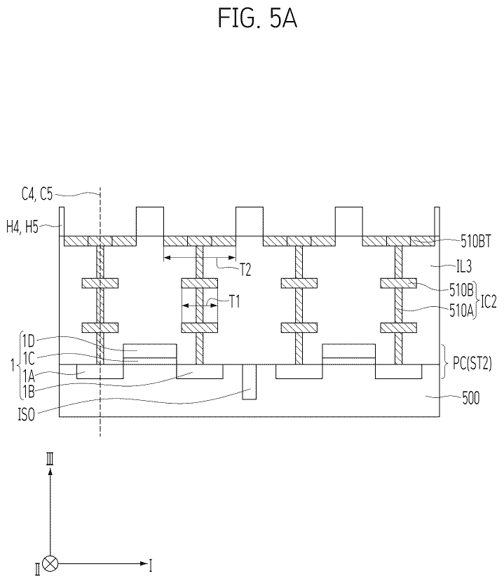

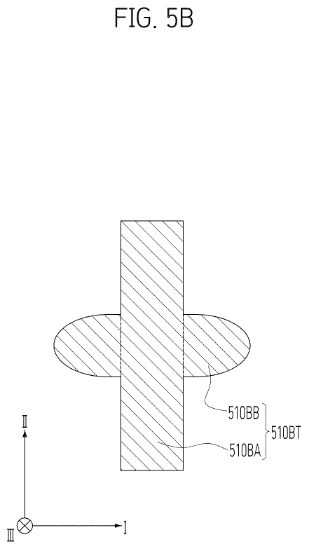

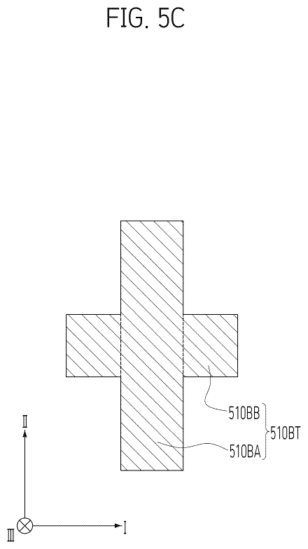

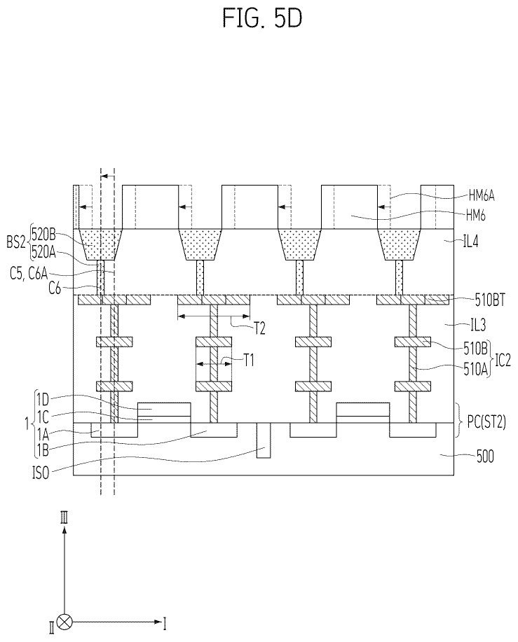

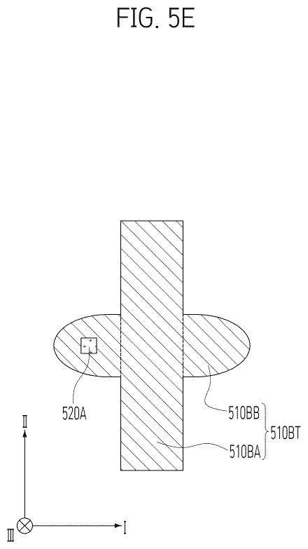

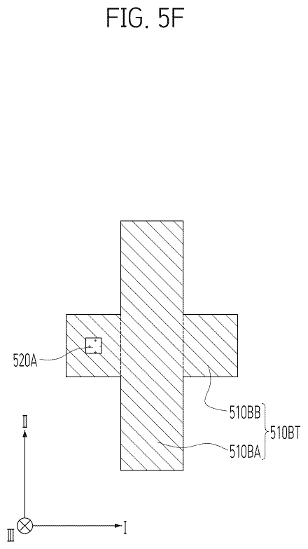

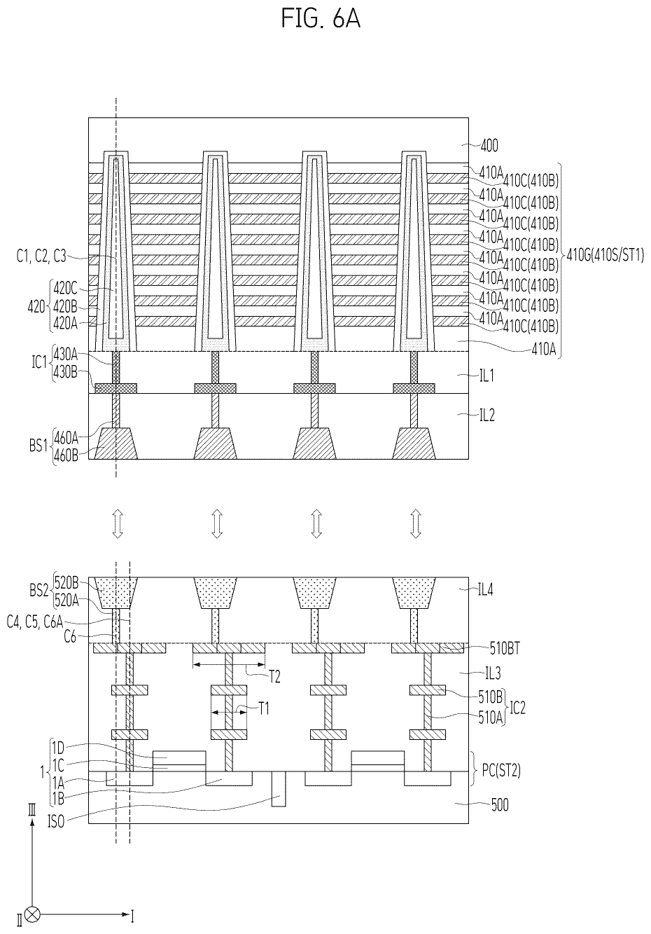

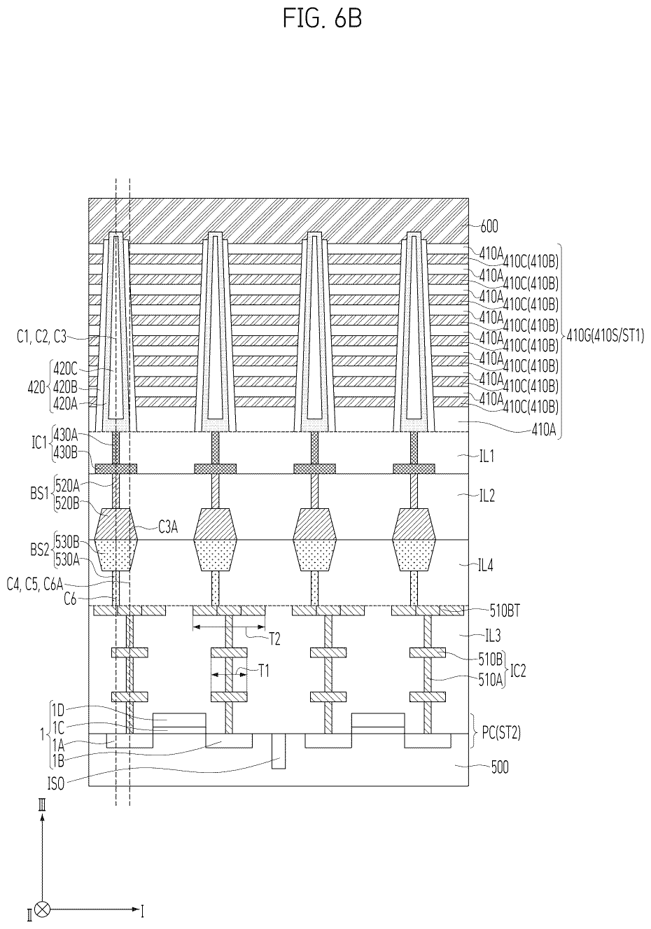

FIG. 4A, FIG. 4B, FIG. 4C, FIG. 5A through FIG. 5F, FIG. 6A, and FIG. 6B illustrate a semiconductor device formed utilizing a method of manufacturing a semiconductor device according to an embodiment of the present disclosure.

Referring to FIG. 4A, a first structure ST1 is formed on a first substrate 400. For example, first material layers 410A are alternately stacked with second material layers 410B to form a stack 410S. The first material layers 410A may include an insulating material such as oxide, and the second material layers 410B may include a sacrificial material such as nitride.

Channel structures 420 extending through the stack 410S are formed. A first hard mask HM1 having a first central axis C1 is formed on the stack 410S. The stack 410S is etched using the first hard mask HM1 as an etching barrier to form channel holes. The channel structures 420 are formed in the channel holes. In this example, the channel structures 420 have the first central axis C1. Each of the channel structures 420 includes a channel layer 420A, a memory layer 420B surrounding the channel layer 420A, and an insulating core 420C within the channel layer 420A.

A slit (not shown) extending through the stack 410S is formed to replace the second material layers 410B with third material layers 410C. Accordingly, a gate structure 410G in which the first material layers 410A alternately stacked the third material layers 410C is formed. The third material layers 410C include conductive lines such as a word line, a bit line, a selection line, and so forth. The third material layers 410C may include a conductive material such as tungsten. When the second material layers 410B include a conductive material, a process including replacing the second material layers 410B with the third material layers 410C is not performed. In this example, the stack 410S is the gate structure 410G.

Referring to FIG. 4B, a first interconnection structure IC1 having a second central axis C2 is formed on the first structure ST1. A first interlayer insulating layer IL1 is formed on the gate structure 410G. A second hard mask HM2 having the second central axis C2 is formed on the first interlayer insulating layer IL1. In this example, the second central axis C2 is aligned with the first central axis C1.

During a process of forming the channel structures 420 and so forth, the location of first central axis C1 of the channel structures 420 may move or change due to process-related causes. In this example, the second central axis C2 of the second hard mask HM2 that forms the first interconnection structure IC1 on the channel structures 420 and the first central axis C1 are moved, adjusted, or aligned with the first central axis C1. For example, a preliminary second hard mask HM2A has a preliminary second central axis C2A, an alignment degree of the preliminary second central axis C2A and the first central axis C1 is checked or compared, for example, by measuring a distance between the preliminary second central axis C2A and the first central axis C1 to determine an adjustment value, and the second hard mask HM2 is formed based on the adjustment value.

The first interconnection structure IC1 is formed within the first interlayer insulating layer IL1 using the second hard mask HM2 as an etching barrier. The first interconnection structure IC1 includes first connection vias 430A and first connection lines 430B. The first connection vias 430A are connected to corresponding channel structures 420. The first connection lines 430B are aligned with the channel structures 420. The first connection lines 430B are conductive lines used, for example, as bit lines. The first interconnection structure IC1 may include a conductive material such as tungsten.

Referring to FIG. 4C, a first bonding structure BS1 having a third central axis C3 is formed on the first interconnection structure IC1. A second interlayer insulating layer IL2 is formed on the first interlayer insulating layer IL1. A third hard mask HM3 having the third central axis C3 is formed on the second interlayer insulating layer IL2. The third central axis C3 is aligned with the first central axis C1. The third hard mask HM3 is formed according to the adjustment value used during the process of forming the second hard mask HM2. For example, the third hard mask HM3 is formed by moving or adjusting a preliminary third hard mask HM3A by an adjustment value used to move or align the second hard mask HM2 to the first central axis. The first bonding structure BS1 includes first bonding vias 440A and first bonding pads 440B.

Referring to FIG. 5A, a second structure ST2 is formed on a second substrate 500. For example, a peripheral circuit PC is formed on the second substrate 500. The peripheral circuit PC includes a transistor 1 or the like. The transistor 1 includes junctions 1A and 1B, a gate insulating layer 1C, and a gate electrode 1D. The second structure ST2 is formed using a fourth hard mask HM4 having a fourth central axis C4. The fourth central axis C4 is misaligned with the first central axis C1.

A second interconnection structure IC2 is formed on the second structure ST2. The second interconnection structure IC2 is formed within a third interlayer insulating layer IL3. The third interlayer insulating layer IL3 is formed on the second substrate 500 and the peripheral circuit PC or second structure. The second interconnection structure IC2 is formed using a fifth hard mask HM5 having a fifth central axis C5. The fifth central axis C5 is aligned with the fourth central axis C4 and is misaligned with the first central axis C1.

The second interconnection structure IC2 includes second connection vias 510A and second connection lines 510B. The second connection lines 510B are formed on the second connection vias 510A. For example, each of uppermost second connection lines 510BT includes a body 510BA extending in a second direction II and protrusions 510BB protruding from the body 510A in a first direction I, for example, orthogonal to the second direction II. The protrusions 510BB may have a quadrangular shape as shown in FIG. 5C and FIG. 5F or an elliptical shape as shown in FIG. 5B and FIG. 5E. The disclosure is not limited to these examples, and the protrusions 510BB may have a circular shape and so forth. The additional first connection lines 510B are formed having a first width T1, and the uppermost first connection lines 510BT are formed having a second width T2 greater than the first width T1.

Referring to FIG. 5D, a second bonding structure BS2 having a sixth central axis C6 is formed on the second interconnection structure IC2. For example, the second bonding structure BS2 is formed using a sixth hard mask HM6 having the sixth central axis C6. The sixth central axis C6 is aligned with the first central axis C1 and is misaligned with the fifth central axis C5. The sixth hard mask HM6 is formed according to an adjustment value used during the process of aligning the second hard mask HM2. For example, the sixth hard mask HM6 is formed by moving or adjusting a preliminary sixth hard mask HM6A by the adjustment value using during aligning the second hard mask HM2 to the first central axis C1.

The second bonding structure BS2 includes second bonding vias 520A and second bonding pads 520B. The second bonding vias 520A are correspondingly connected to the uppermost second connection lines 510BT. During this process, even though the sixth central axis C6 of the second bonding vias 520A and the fifth central axis C5 of the uppermost second connection lines 510BT are misaligned, a width of the uppermost second connection lines 510BT is formed wide enough to obtain a sufficient landing margin between the second interconnection structure IC2 and the second bonding structure BS2, thus the second bonding vias 520A and the uppermost second connection lines 510BT are connected.

Referring to FIG. 6A, the first bonding structure BS1 and the second bonding structure BS2 are bonded. For example, the first bonding pads 440B are correspondingly bonded to the second bonding pads 520B. Accordingly, the first structure ST1 and the second structure ST2 are electrically connected through the first interconnection structure IC1, the first bonding structure BS1, the second bonding structure BS2, and the second interconnection structure IC2.

Referring to FIG. 6B, the first substrate 400 is removed to expose the channel structures 420. The memory layer 420B of the channel structures 420 is partially removed to expose the channel layer 420A. A source structure 600 is formed on the channel structures 420. Accordingly, the source structure 600 is formed on the first structure ST1. In this example, the channel layer 420A and the source structure 600 are connected.

According to an embodiment of the present disclosure, after forming the first structure ST1 having the first central axis C1, the second hard mask HM2 and the third hard mask HM3 that form the first interconnection structure IC1 and the first bonding structure BS1 may be moved, aligned, adjusted, or calibrated, and the sixth hard mask HM6 that forms the second bonding structure BS2 may be moved, aligned, adjusted, or calibrated to the first central axis C1. The second hard mask HM2, the third hard mask HM3, and the sixth hard mask HM6 are separately manufactured.

In an embodiment when only the sixth hard mask HM6 that forms the second bonding structure BS2 bonded to the first bonding structure BS1 are aligned, adjusted, or calibrated to the first central axis C1, the fourth hard mask HM4 and the fifth hard mask HM5 that form the second structure ST2 and the second interconnection structure IC2 need not be aligned, adjusted, or calibrated to the first central axis C1. In this example, because the fourth hard mask HM4 and the fifth hard mask HM5 need not be separately manufactured, manufacturing costs of the semiconductor device may be reduced.

According to an embodiment of the manufacturing method, when the uppermost second connection lines 510BT of the second interconnection structure IC2 are formed with a relatively greater width than the additional second connection lines 510B, and only the sixth hard mask HM6 that forms the second bonding structure BS2 formed on the second interconnection structure IC2 may be aligned, moved, adjusted, or calibrated. In this example, because the fourth hard mask HM4 and the fifth hard mask HM5 that form the second structure ST2 and the second interconnection structure IC2 need not be separately manufactured, manufacturing costs of the semiconductor device may be reduced.

Concepts are disclosed in conjunction with examples and embodiments. Those skilled in the art will understand that various modifications, additions, combinations, and substitutions are possible without departing from the scope and technical concepts of the present disclosure. The embodiments disclosed in the present specification should be considered from an illustrative standpoint and not a restrictive standpoint. Therefore, the scope of the present disclosure is not limited to these descriptions. All changes within the meaning and range of equivalency of the claims are included within their scope.

What is claimed is:

1. A semiconductor device comprising:
a first structure having a first central axis;
a first interconnection structure located on the first structure and having a second central axis aligned with the first central axis;
a first bonding structure located on the first interconnection structure and having a third central axis misaligned with the first central axis;
a second bonding structure located on the first bonding structure and having a fourth central axis misaligned with the first central axis;
a second interconnection structure located on the second bonding structure and having a fifth central axis misaligned with the first central axis; and
a second structure located on the second interconnection structure and having a sixth central axis misaligned with the first central axis.

2. The semiconductor device of claim 1, wherein the third central axis, the fourth central axis, the fifth central axis, and the sixth central axis are aligned.

3. The semiconductor device of claim 1, wherein the first structure includes a peripheral circuit;
the first interconnection structure includes first connection vias and first connection lines;
the first bonding structure includes first bonding vias and first bonding pads;
the second structure includes a gate structure and channel structures extending through the gate structure;
the second interconnection structure includes second connection vias and second connection lines; and
the second bonding structure includes second bonding vias and second bonding pads.

4. The semiconductor device of claim 3, wherein the first connection lines include a first set of first connection lines and a second set of first connection lines, and
each of the first set of first connection lines includes a body extending in a second direction and protrusions protruding from the body in a first direction orthogonal to the second direction.

5. The semiconductor device of claim 4, wherein each of the second set of first connection lines has a first width, and
each of the first set of first connection lines has a second width greater than the first width.

6. The semiconductor device of claim 4, wherein the protrusions have a quadrangular shape or an elliptical shape.

7. The semiconductor device of claim 4, wherein at least one of the first connection vias is connected to the peripheral circuit;
the first set of first connection lines are correspondingly connected to the first connection vias;
the second set of first connection lines interconnect the first connection vias;
the first bonding vias are correspondingly connected to the first set of first connection lines; and
the first bonding pads are correspondingly connected to the first bonding vias.

8. The semiconductor device of claim 7, wherein the first bonding vias are correspondingly connected to the protrusions.

9. The semiconductor device of claim 3, wherein the second connection vias are correspondingly connected to the channel structures;
the second connection lines are correspondingly connected to the second connection vias;
the second bonding vias are correspondingly connected to the second connection lines; and
the second bonding pads are correspondingly connected to the second bonding vias.

10. The semiconductor device of claim 3, wherein the second connection lines are correspondingly aligned with the channel structures.

11. The semiconductor device of claim 3, further comprising a source structure located on the second structure.

12. The semiconductor device of claim 11, wherein each of the channel structures includes a channel layer and a memory layer surrounding the channel layer, and
the channel layer is connected to the source structure.

13. The semiconductor device of claim 3, wherein the second bonding pads are correspondingly connected to the first bonding pads.

14. A method of manufacturing a semiconductor device, the method comprising:
forming a first structure using a first hard mask having a first central axis;
aligning a second central axis of a second hard mask with the first central axis;
forming a first interconnection structure connected to the first structure using the second hard mask;
aligning a third central axis of a third hard mask with the first central axis;
forming a first bonding structure connected to the first interconnection structure using the third hard mask;
forming a second structure using a fourth hard mask having a fourth central axis misaligned with the first central axis;
forming a second interconnection structure connected to the second structure using a fifth hard mask having a fifth central axis misaligned with the first central axis;
aligning a sixth central axis of a sixth hard mask with the first central axis;
forming a second bonding structure connected to the second interconnection structure using the sixth hard mask; and
bonding the first bonding structure to the second bonding structure.

15. The method of claim 14, wherein forming the second interconnection structure comprises:
forming second connection vias; and
forming, on the second connection vias, a first set of second connection lines, each including a body extending in a second direction and protrusions protruding from the body in a first direction orthogonal to the second direction.

16. The method of claim 15, wherein the protrusions have a quadrangular shape or an elliptical shape.

17. The method of claim 15, wherein forming the second bonding structure comprises:
forming a second bonding via connected to one of the protrusions; and
forming a second bonding pad on the second bonding via.

18. The method of claim 14, wherein the sixth hard mask is aligned with the first central axis by adjusting the sixth hard mask by an adjustment used to align the second axis of the second hard mask with the first central axis.

19. The method of claim 14, wherein the fourth central axis and the fifth central axis are aligned.

20. The method of claim 14, wherein forming the first structure includes forming a gate structure and channel structures extending through the gate structure;
wherein forming the first interconnection structure includes forming first connection vias and first connection lines;
wherein forming the first bonding structure includes forming first bonding vias and first bonding pads;
wherein forming the second structure includes forming a peripheral circuit;
wherein forming the second interconnection structure includes forming second connection vias and second connection lines; and
wherein forming the second bonding structure includes forming second bonding vias and second bonding pads.

21. The method of claim 20, wherein forming the second connection lines includes forming a first set of second connection lines and a second set of second connection lines,
wherein the second set of second connection lines are formed having a first width, and the first set of second connection lines are formed having a second width greater than the first width.

22. The method of claim 21, wherein the first connection vias are correspondingly connected to the channel structures;
the first connection lines are correspondingly connected to the first connection vias;
the first bonding vias are correspondingly connected to the first connection lines; and
the first bonding pads are correspondingly connected to the first bonding vias.

23. The method of claim 21, wherein at least one of the second connection vias is connected to the peripheral circuit;
the first set of second connection lines are correspondingly connected to the corresponding second connection vias;
the second set of second connection lines interconnect the second connection vias;
the second bonding vias are correspondingly connected to the first set of second connection lines; and
the second bonding pads are correspondingly connected to the second bonding vias.

24. The method of claim 20, wherein the first connection lines are correspondingly aligned with the channel structures.

25. The method of claim 20, further comprising forming a source structure on the first structure.

26. The method of claim 25, wherein each of the channel structures includes a channel layer and a memory layer surrounding the channel layer, and
the channel layer is connected to the source structure.

27. The method of claim 20, wherein the second bonding pads are correspondingly connected to the first bonding pads.

28. A semiconductor device comprising:
a first wafer including a first structure having a first central axis, a second structure having a second central axis misaligned with the first central axis; and
a second wafer bonded to the first wafer and including third structure having a third central axis misaligned with the first central axis and a fourth structure having a fourth central axis misaligned with the first central axis.

29. The semiconductor device of claim 28, wherein the first structure includes a second set of first connection lines having a first width and a first set of first connection lines having a second width greater than the first width.
